(19) United States
(12) Patent Application Publication
(10) Pub. No.: US 2009/0250824 A1
(43) Pub. Date: Oct. 8, 2009

(54) METHOD AND APPARATUS TO REDUCE PIN VOIDS

(76) Inventors: Xiwang Qi, Scottsdale, AZ (US); Charan K. Gurumurthy, Higley, AZ (US); Tamil Selvy Selvamuniandy, Chandler, AZ (US); Isao Yamada, Tokyo (JP)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/098,311

(22) Filed: Apr. 4, 2008

(51) Int. Cl. H01L 23/48; H01L 21/00

(52) U.S. Cl. 257/786; 438/121; 257/E23.015

(57) ABSTRACT

A semiconductor package comprises a substrate that utilizes one or more pins to form external interconnects. The pins are bonded to bonding pads on the substrate by solder. The pins may each has a pin head that may have a bonding surface, wherein the bonding surface may comprises a center portion and a side portion that is tapered away relative to the center portion. In some embodiments, the bonding surface may comprise a round shape. In some embodiments, a gas escape path may be provided by the shape of the bonding surface to increase pin pull strength and/or solder strength. The package may further comprise a surface finish that may comprise a palladium layer with a reduced thickness to reduce the amount of palladium based IMC precipitation into the solder.

### BACKGROUND

Some pin grid array (PGA) packages may utilize pins to form external interconnects on substrates of the packages. A pin may be bonded to a pad on a substrate. Solders or solder pastes may be used to bond pins to pads. A pad may comprise a surface finish that may utilize palladium to protect pads (e.g., Cu) from oxidation. Some factors may impact pin pull strength or solder strength, including palladium concentration in the solder and palladium and/or palladium based intermetallic compound (IMC) precipitation in the solder. In some packages, volatile gases from flux and/or organic components in the solder may be trapped in the solder to form voids, e.g., during solder reflow, due to geometric restriction of a solder mask opening and pin head shape.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 is a schematic diagram of an embodiment of a semiconductor package.

FIG. 2 is a schematic diagram of an embodiment of a substrate that may comprise a pin.

FIG. 3A to 3E are schematic diagrams of some embodiments of a pin.

FIG. 4 is a flow chart of a method that may be used to provide the package of FIG. 1.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

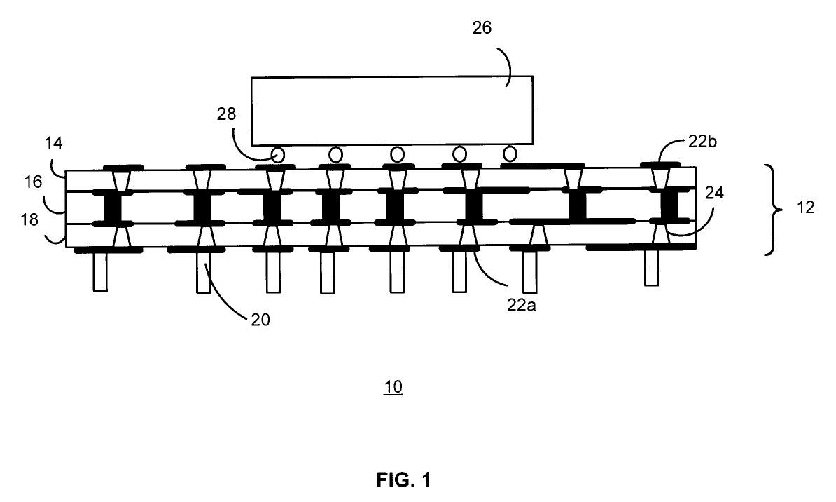

FIG. 1 illustrates an embodiment of a semiconductor package 10 that may comprise a multi-layered substrate 12. Referring to FIG. 1, in one embodiment, the multi-layered substrate 12 may comprise a first buildup layer 14, a first substrate 16, and a second buildup layer 18; however, in some embodiments, a substrate with any different number of layers or other structure may be utilized. One example of the substrate 12 may comprise a printed circuit board (PCB) or a printed wiring board (PWB); however, any other suitable substrate may be utilized, including flex substrates such as folded flex substrates or flexible polyimide tape, laminate substrates, buildup substrates, ceramic substrates, flame retardant (FR-4) substrate, or tape automated bonding (TAB) tape material.

Referring to FIG. 1, the substrate 12 may comprise a set of upper bonding pads 22b and lower bonding pads 22a; however, in some embodiments, patterned conductive layers, bonding lands, conductive lands, routings, wirings or any other suitable interconnects may be utilized. In one embodiment, a lower pad 22a may be electrically coupled to an upper pad 22b via a conductive path 24 in the substrate 12. Examples of the conductive path 24 may comprise plated through holes, vias or any other interconnects. The substrate 12 may comprise a pin grid array (PGA) substrate that may comprise a set of one or more pins 20. In one embodiment, a pin 20 may be coupled to a pad 22. The substrate 12 may be coupled to a mother board (not shown), e.g., by one or more pins 20.

Referring to FIG. 1, an integrated circuit (IC) module 26 may be provided on and coupled to the substrate 12. In one embodiment, the IC module 26 may comprise a set of one or more bumps 28 that may each be coupled to an upper pad 22b; however, in some embodiments, any other suitable interconnects may be utilized to coupled the IC module 26 with the substrate 12, such as conductive adhesive film, conductive protrusions. Examples of the IC module 26 may comprise flash memory, static random access memory (SDRAM), digital signal processor (DSP), application specific integrated circuit (ASIC), logic circuits, or any other circuits or devices. While FIG. 1 illustrates IC module 26, in some embodiments, any other structure may be utilized. For example, one or more dies (not shown) may be provided on and coupled to the substrate 12.

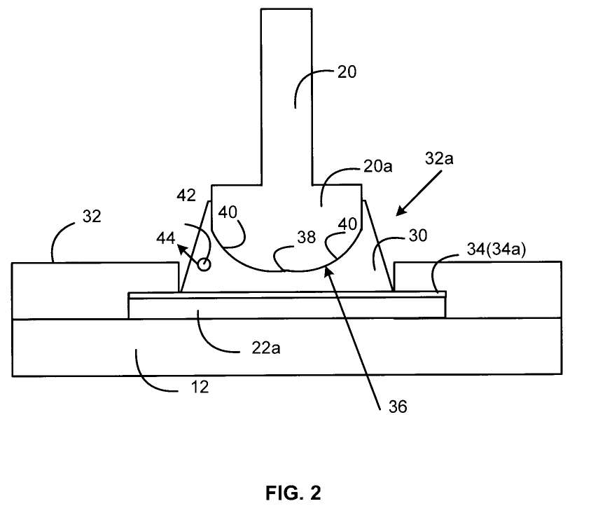

FIG. 2 illustrates an enlarged schematic diagram of an embodiment of the substrate 12. Referring to FIG. 2, a mask 32 may be provided on the substrate 12. In one embodiment, the mask 32 may comprise an opening 32a that may selectively expose a portion of a bonding pad 22a or the whole bonding pad 22a. In one embodiment, a layer of solder 30, e.g., a solder paste layer may be provided on the exposed portion of the pad 22a through the opening 32. A pin 20 may be bonded to the pad 22a via the solder 30. Examples of the solder 30 may comprise SnSb, SnPb, Sn, or SnAg or any other solder materials.

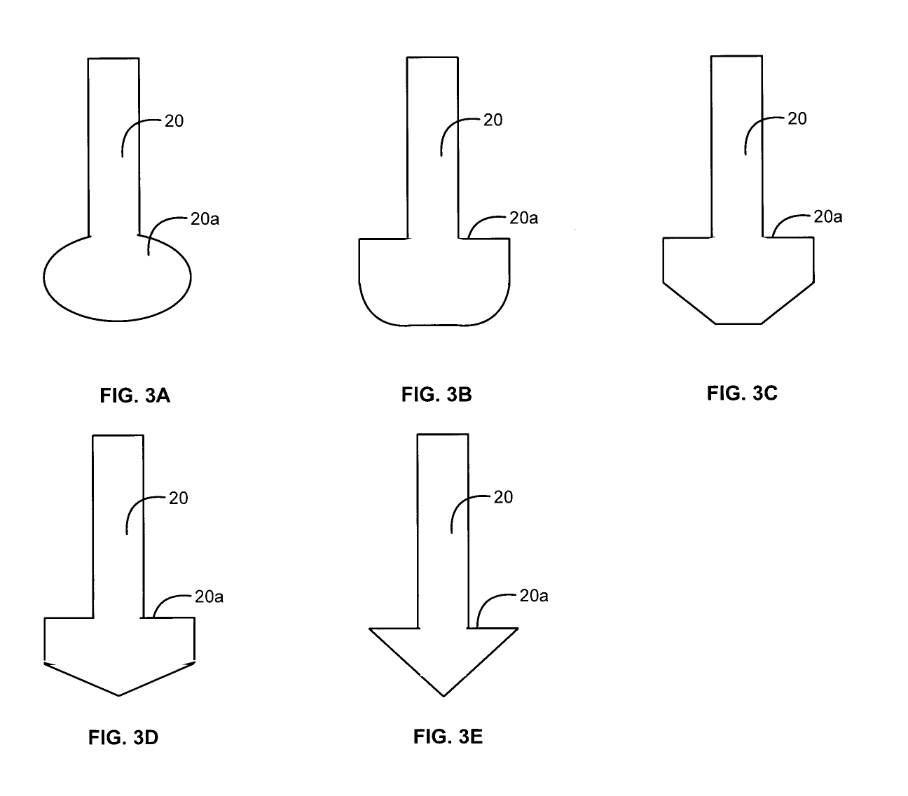

In one embodiment, the pin 20 may comprise a pin head 20a that may have a bonding surface 36 to be bonded to the bonding pad 22a. In one embodiment, the bonding surface 36 may comprise a center portion 38 and side portion 40. The side portion 40 may be tapered away from the bonding pad 22a relative to the center portion 38. In another embodiment, the center portion 38 may be disposed at a lower position or closer to the bonding pad 22a than the side portion 40. In yet another embodiment, the bonding surface 36 may have a round shape. In another embodiment, a distance from the center portion 38 to the bonding pad 22a may be less than a distance from the side portion 40 to the bonding pad 22a. For example, referring to FIG. 2, the pin head 20a may have a round shape at the bonding surface 36. In another embodiment, referring to FIG. 3A, the pin head 20a may have a spherical shape. In another embodiment, referring to FIGS. 3B to 3D, the center portion 38 may have a flat shape. In yet another embodiment, for example, referring to FIGS. 3D and 3E, the side portion 40 may have a flat shape and may form an angle relative to the bonding pad 22a or the substrate 12 or the center portion 38.

While FIG. 2 and FIGS. 3A-3E illustrate embodiments of the shape of the pin head 20a, in some embodiments, the pin head 20a may have any other suitable shape where the side portion 40 tapers away from the substrate 12. While FIG. 2 and FIGS. 3A-3E illustrates that the pin head 20a may have a greater width than other portions of the pin 20; however, in some embodiments, the pin 20 may have equal or lesser width. While some embodiments may utilize pins as external interconnects, in some embodiments, any other interconnects may be utilized, including protruding interconnects. In other embodiments, the pin head may have a symmetric or asymmetric shape.

Referring to FIGS. 2, 3A-3E, in one embodiment, the pin head 20a may have the bonding surface 36 to provide a gas escape path 44 between the bonding surface 36 and the bonding pad 22a. In one embodiment, the gas escape path 44 may allow gas to escape from a pin void 42 in the solder 30 and eliminating or reducing the size of the pin void 42. In another embodiment, the gas escape path 44 may enhance degassing from melted solder material, e.g., during pinning or solder reflow and may increase pin pull strength and/or solder strength. In one embodiment, a pin pull strength may be in a range from around 2.5 kgf to around 3.0 kgf. In yet another embodiment, the gas escape path 44 to reduce or eliminate a pin void size may prevent palladium based IMC from precipitating (e.g., at room temperature) into the solder 30 to reduce solder aging related pin pull strength/solder strength degradation.

Referring to FIG. 2, a surface finished 34 may be provided on the bonding pad 22a. The surface finish 34 may comprise palladium. In another embodiment, the surface finish 34 may comprise nickel, gold or any other suitable metals. In one embodiment, an amount of palladium in the surface finish 34 may be reduced to control or reduce palladium concentration in the solder 30 and/or prevent palladium based IMC precipitation into the solder 30 to maintain a pin pull strength of the pin 20 or solder strength. For example, the surface finish 34 may comprise a palladium layer 34a. The palladium layer 34a may have a thickness in a range from around 0.01 um to around 0.05 um. In another embodiment, the palladium layer 34a may have a thickness in a range from around 0.02 um to around 0.04 um. In some embodiments, the bonding pad 22a may have a bonding surface that may have a shape similar to the shape of the bonding surface 36 as described with reference to FIGS. 2, 3A-3E, to provide a gas escape path between the bonding pad 22a and the bonding surface 36.

In one embodiment, a reduction in palladium may reduce palladium concentration in the solder 30 below solubility of palladium or palladium based IMC at room temperature. In another embodiment, the reduction of palladium may prevent palladium and/or palladium based IMC precipitation into the solder 30. In yet another embodiment, reduction of palladium may retard palladium assisted solder aging.

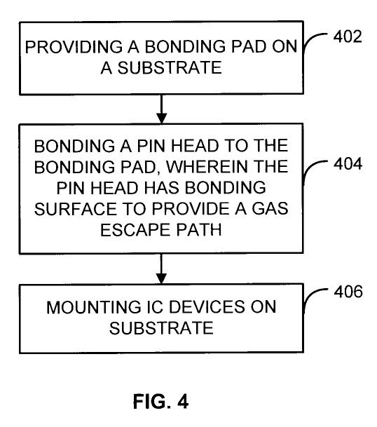

FIG. 4 illustrates an exemplary embodiment of a method that may be used to provide, e.g., the semiconductor package 10 of FIG. 1. In block 402, a substrate, e.g., substrate 12 may be provided. In block 404, a bonding pad 22a may be provided on the substrate 12. In one embodiment, the bonding pad 22a may comprise copper. In another embodiment, a surface finish 34 may be provided on the bonding pad 22a. For example, the surface finish 34 may comprise a palladium layer 34a; however, the surface finish 34 may comprise gold, nickel or any other suitable metals. In another embodiment, the surface finish 34 may comprise a nickel layer (not shown) that may be disposed under the palladium layer 34a. In yet another embodiment, the surface finish 34 may comprise a gold layer (not shown) that may be disposed on the palladium layer 34a.

In block 406, one or more pins 20 may be bonded to the bonding pad 22a. In one embodiment, a solder mask, e.g., mask 32 of FIG. 2 may be provided on the substrate 12. The mask 32 may be patterned to have an opening 32a to expose a portion of or a whole portion of the bonding pad 22a. The surface finish 34 may comprise a palladium layer 34a that may have a reduced thickness to prevent or reduce palladium concentration in the solder 30. Solder 30 may be used to bond a pin 20 to the bonding pad 22a. In one embodiment, a paste of solder 30 may be provided on the bonding pad 22a through the opening 32a. The paste of solder 30 may be reflowed to bond the bonding pad 22a to a bonding surface 36 of the pin 20.

In one embodiment, the bonding surface 36 may comprise a center portion 38 that may be positioned lower than side portion 40 of the bonding surface 36 to provide a gas escape path 44 between the bonding surface 36 and the bonding pad 22a. In another embodiment, the side portion 40 of the bonding surface 36 may be tapered away relative to the center portion 38 of the bonding surface 36. In another embodiment, the pin head 20a may have a spherical shape, a tapered shape or any other shape that may provide a gas escape path between the pin head 20a and the bonding pad 22a. In one embodiment, the gas that may be trapped in the solder 30 to form a pin void 42, e.g., during solder reflow, may escape from the solder 30 via the gas escape path 44.

In another embodiment, degassing may be performed to the solder 30 to allow gas in a pin void 42 to escape from the solder 30 via the gas escape path 44 during solder reflow. In yet another embodiment, the pin head 20a with the gas escape path 44 may eliminate a pin void in the solder 30 to prevent palladium and/or palladium based IMC in the surface finish 34 from precipitating into the solder 30, e.g., at least at room temperature. The pin head 20a with the gas escape path 44 may prevent the palladium based solder aging in the solder 30.

In block 408, one or more IC devices, e.g., IC module 26 of FIG. 1 may be mounted and coupled to the substrate 12; however, in some embodiments, one or more dies may be mounted to the substrate 12. While the method of FIG. 4 is illustrated to comprise a sequence of processes, the method in some embodiments may perform illustrated processes in a different order.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A semiconductor package, comprising:
a substrate;
a bonding pad disposed on the substrate and coupled to the substrate;
a pin that comprises a pin head, wherein the pin head comprises a bonding surface to be bonded to the bonding pad, the bonding surface has a center portion and a side portion, wherein the side portion is tapered away relative to the center portion to provide a gas escape path between the bonding surface and the bonding pad.

2. The package of claim 1, wherein the gas escape path is to enhance degassing from a solder that is to bond the bonding surface to the bonding pad.

3. The package of claim 1, wherein the bonding surface has a round shape.

4. The package of claim 1, wherein a portion of one of the center portion and the side portion is flat.

5. The package of claim 1, further comprising:
a palladium layer that is provided on the bonding pad, wherein the palladium layer has a thickness in a range of 00.1 um to 0.05 um.

6. The package of claim 1, further comprising:
a palladium layer that is provided on the bonding pad, wherein the palladium layer has a thickness in a range of 0.02 um to 0.04 um.

7. The package of claim 1, further comprising:
a palladium layer that is provided on the bonding pad, wherein the gas escape path is to reduce palladium concentration in a solder that is to bond the bonding surface to the bonding pad.

8. The package of claim 1, wherein the pin has a pin pull strength in a range from 2.5 kgf to 3.0 kgf.

9. A method to fabricate a semiconductor package, comprising:
providing a bonding pad on a substrate, wherein the bonding pad is electrically coupled to a substrate;
bonding a pin to the bonding pad, wherein the pin comprises a pin head that comprises a bonding surface, the bonding surface comprising a center portion and a side portion, wherein a distance from the center portion to the bonding pad is less than a distance from the side portion to the bonding pad to provide a gas escape path.

10. The method of claim 9, further comprising:
providing a palladium layer on the bonding pad, wherein the palladium layer has a thickness in a range of 0.01 um to 0.05 um.

11. The method of claim 9, further comprising:
providing a palladium layer on the bonding pad, wherein the palladium layer has a thickness in a range of 0.02 um to 0.04 um.

12. The method of claim 9, wherein the bonding surface has a round shape.

13. The method of claim 9, further comprising:
providing a solder to bond the pin head to the bonding pad, wherein the gas escape path is to reduce gas trapped in the solder.

14. The method of claim 9, wherein the side portion is tapered away relative to the center portion.

15. The method of claim 9, further comprising:
providing a palladium layer on the bonding pad, wherein the gas escape path is further to reduce palladium concentration in a solder to bond the bonding surface to the bonding pad.
